(19) United States
(12) Patent Application Publication
(10) Pub. No.: US 2026/0117366 A1
(43) Pub. Date: Apr. 30, 2026

(54) TRANSPARENT COATED PLASTIC WINDOW INSERT

(71) Applicant: NXLITE TECHNOLOGIES INC., Canton Township, MI (US)

(72) Inventors: Jose NUNEZ-REGUEIRO, Ann Arbor, MI (US); Paulo Cesar DE MOURA, Canton, MI (US); Nazir Pyarali KHERANI, Toronto (CA); Alexey KRASNOV, Canton, MI (US)

(21) Appl. No.: 19/366,891

(22) Filed: Oct. 23, 2025

Related U.S. Application Data
(60) Provisional application No. 63/711,987, filed on Oct. 25, 2024.

(51) Int. Cl. C23C 14/34; C23C 14/08; C23C 14/20

(52) U.S. Cl. CPC C23C 14/34; C23C 14/08; C23C 14/20

(57) ABSTRACT

The present disclosure provides a transparent lightweight and economical retrofit insert for enhanced thermal insulation of existing residential and commercial windows. The insert comprises a plastic pane coated on both of its major surfaces with coatings of comparable thickness. One of the two coatings is a silver-based solar-control coating intended to partially block direct radiative heat of the sun as well as to provide emissivity control. The second coating can be solar-control, low-emissivity, or optically non-functional coating. Its primary role is to provide symmetry in the concentration gradients of permeated environmental moisture across the thickness of the pane in respect to its two major surfaces. Said symmetry provides comparable levels of the coefficients of hygroscopic and thermal expansion which prevents the insert from warping while in use in humid environment.

### FIELD

The present disclosure relates to a transparent coated plastic window insert and, particularly, to an insert with a reduced sensitivity to adverse effects of moisture absorption.

### BACKGROUND

Engineering plastics, such as polycarbonate (PC), polymethyl methacrylate (PMMA or otherwise known as acrylics), and polyethylene terephthalate (PET), are used at an accelerating pace in a variety of applications, including architectural glazing, due to their lower mass density light-weight character, good thermal insulation, longevity, low cost, and reduced brittleness compared to glass. Besides, plastics—especially PMMA—possess high optical transparency, which is a welcomed attribute in windows and skylights in commercial and residential buildings. PMMA is known to consumers by trade names such as Plexiglas, Acrylite, Crylux, Perclax, Perspex, Astariglas, and Lucite. Most recently, coated and uncoated PMMA panes have been suggested as retrofit inserts to improve thermal insulation of existing low-performance windows without expensive and cumbersome rip-and-replace.

A typical window comprises a single glass pane or a set of two or more glass panes supported by a frame and optionally assembled as an insulating glass unit (IGU). Examples of glass include soda-lima silicate, aluminosilicate, lithium aluminosilicate, borosilicate, etc. Some IGUs are filled with inert gas, such as argon, to further improve thermal insulation. Adding a PMMA pane to a single- or double-pane window as an inexpensive and nonintrusive retrofit offers extra thermal protection by reducing the flow of convectional heat between the interior of the building and the environment. Coating the insert with a solar-control coating, such as a silver-based single-(Ag1) or double-silver (Ag2) thin-film wavelength-selective optical-interference stack or a transparent-conductive-oxide (TCO) based low-emissivity (low-E) coating further improves thermal performance by blocking a significant portion of radiative near-infrared (near-IR) heat from the sun and/or reducing the emissivity of the glazing that mitigates the loss/gain of mid-infrared (MIR) room/ambient heat. Both types of coatings are discussed in detail in [https://doi.org/10.1016/j.optmat.2023.113807]. Silver-based coatings offer excellent IR reflection and, at the same time, the smallest light absorption in the visible spectrum among all metals. They are, however, not free from drawbacks, such as susceptibility to scratches due to processing and environmental corrosion if exposed to the air for a prolonged time. For this reason, they are often referred to as ‘soft’ coatings. TCO-based coatings, on the other hand, are more durable and environmentally stable and, therefore, are often called ‘hard’ coatings. The most widely used example of the latter is indium-tin-oxide (ITO) based low-E coating.

Uncoated and coated plastic inserts are known in the art. [https://indowwindows.com/custom-storm-windows] is an example of uncoated plastic inserts. A lightweight composite comprising a PMMA pane bonded to a pane of thin glass is disclosed in [https://fis.tu-dresden.de/portal/en/publications/neerofacade--a-new-concept-of-facade-design-with-lightweight-thin-glassplasticcomposite-panels (48c37354-e449-4f49-aadb-57eca148f625).html]. PMMA coated with solar-control coatings, including those based on silver (FIG. 1), are disclosed in [CA2,375,256, U.S. Pat. No. 5,028,759A, and US20100257815A1], wherein the coated substrate is bonded to a thin pane of glass. Most recently, the authors of the present disclosure disclosed in a separate filing a PMMA insert coated with silver-based solar-control coating having improved adhesion [3E Nano U.S. patent application Ser. No. 19/078,390 filed] and environmental stability [3E Nano U.S. patent applications 63/571,002 and PCT/CA2025/050414 filed]. A PET substrate coated with a Ag1 solar-control coating having an enhanced resistance to moisture absorption is reported in [https://doi.org/10.1016/j.mssp.2015.02.051].

Unfortunately, PMMA is prone to atmospheric moisture permeation which causes its elastic (reversible) deformation, also known as swelling. This attribute is defined as linear change in pane dimensions [https://doi.org/10.2172/811193]. If not directly integrated in an argon-filled IGU or protected from both sides, PMMA can absorb up to ˜2% w/w water [https://doi.org/10.1021/la302260a]. Increased moisture content in PMMA was reported to affect the coefficient of hygroscopic expansion (CHE)—a measure of the change in material strain with moisture absorption [https://doi.org/10.1007/BF01139031]. It also causes a linear increase in the coefficient of thermal expansion (CTE) due to decreased cohesive forces between polymer chains [https://doi.org/10.1080/27660400.2021.1993729]. CTE measures how much a material expands or contracts per degree of temperature change. [https://doi.org/10.1007/BF01139031

Over the course of this work, the inventors of the present disclosure discovered that due to symmetrical moisture gradients from the two major surfaces of an uncoated PMMA (FIG. 2A) and thus symmetrical CHE and CTE gradients, the pane swelling results in a linear expansion and not so much in pane warping.

Various reports suggest depositing moisture barriers on plastic substrates, such as rigid panes and flexible films. Examples include transparent barriers on packaging plastics for food industry [https://doi.org/10.1039/d0gc03647a; https://doi.org/10.1016/j.carbpol.2021.118421] and alternating sequences of dielectric layers, such as AlN and Al₂O₃, deposited by sophisticated methods, like atomic layer deposition (ALD) [https://doi.org/10.1116/6.0002057], on plastic rigid substrates. ALD-deposited thin films are particularly known [https://doi.org/10.1016/j.surfcoat.2010.12.001] to have a substantially reduced pinhole density. Also, interfaces between dissimilar ALD-deposited layers are less prone to the formation of dislocations compared to more economical large-scale deposition methods, such as sputtering. Both qualities make ALD materials excellent moisture barriers less prone to moisture permeation, albeit achieved at a higher cost.

The problem, however, unexpectedly arises when a coating with good moisture blocking properties is deposited on only one side of a plastic pane. In this case, an asymmetric moisture uptake takes place across the pane thickness, as depicted in FIG. 2B. The resultant asymmetry in moisture distribution creates a significant difference in both CHE and CTE between two major surfaces of the polymer, thus affecting the Young's modulus [https://doi.org/10.1002/pen.24378]. Together, these two outcomes inevitably cause warping. More specifically, the coated side becomes the concave surface. The larger the pane, the more severe the warping. Blocking moisture absorption from one side of a PMMA pane by bonding it to thin glass is no exception, although the degree of bending in this case is influenced by the rigidity of the resultant composite pane.

A similar effect, albeit to a lesser extent, occurs when one side is coated with a less perfect moisture barrier, such as a much more economical sputtered thin film or thin-film stack (FIG. 2C). Compared to ALD, sputter deposited films are known to have a greater density of voids and other imperfections [https://doi.org/10.1063/5.0088948] which play the role of moisture permeation channels. So, when a sputtered low-E/solar-control coating, such as Ag1 or Ag2, is applied on one side of a plastic, e.g., a PMMA pane, a moisture concentration gradient between the two major surfaces is created over time and the pane bends due to the effects of both CHE and CTE that gives rise to asymmetric strains between coated and uncoated surfaces.

It would be desirable, therefore, to provide a plastic pane coated with a low-E solar-control coating to also have a reduced or no sensitivity to warping due to its exposure to atmospheric moisture.

### BRIEF DESCRIPTION

The present disclosure solves the problem of warping of a coated plastic pane caused by the asymmetry in the profile of absorbed atmospheric moisture content across its thickness. More specifically, the disclosure addresses the problem of warping of a plastic pane coated with a silver-based low-E/solar-control coating on one of its major surfaces. The goal of the disclosure is not to prevent atmospheric moisture from permeating into a coated plastic pane. This task, even if accomplished at all, would require expensive equipment and a time-consuming manufacturing process, such as atomic layer deposition (ALD), the cost of which, especially on a large scale, would undermine the entire concept of fabricating an affordable window insert. Instead, the disclosure is focused on making the moisture permeation properties of the two surfaces similar and hence the moisture concentration profile effectively symmetrical in respect to the two major surfaces of a coated plastic pane. For this, the disclosure provides two coatings—one on each major surface of a pane. At least one of the two coatings of the present disclosure is a sputtered silver-based solar-control coating used to improve thermal insulation. It is crucial that the second coating is also preferably sputter deposited and, preferably, is of a comparable thickness to the first coating thickness.

Besides their main role of mitigating warping, the two coatings do reduce the total level of environmental moisture uptake. This leads to a reduced level of stress exerted on the coating by the pane during its expansion/contraction.

The effect is shown first in FIG. 3A for a Ag-based sputtered coating on one side and an ALD-deposited moisture barrier coating on the opposite side. This combination results in asymmetric moisture concentration gradients at the two major surfaces of the pane which lead to its warping due to asymmetry in strain principally due to differences in the coefficient of hygroscopic expansion (CHE) at the two major surfaces, as well as differences in the coefficient of thermal expansion (CTE) at the two major surfaces. FIG. 3B depicts the scenario when a sputtered coating of a comparable thickness to the first coating thickness is deposited on the opposite major surface of the pane. In this case, comparable levels of moisture uptake occur from both sides of the pane, so approximately equal values of strain result—arising due to the attainment of similar levels of moisture permeation through the coatings and absorption at both surfaces that in turn cause no or little warping.

In the first aspect of the disclosure, therefore, a second coating is provided to equalize the levels of moisture uptake at the two major surfaces of the pane caused by the silver-based solar-control coating deposited on one side. The use of two approximately symmetrical coatings minimizes the total resultant moisture-induced strain of the pane due to the symmetry in the moisture-level-dependent CHE's and CTE's. The benefit of this approach increases for panes with large dimensions, such as those used in large-size architectural windows, in which case inserts with asymmetrical CHE and CTE profiles would inevitably warp.

In a second aspect of the disclosure, a second coating deposited on the opposite to the silver-based coating surface has the additional functionality of also being a solar-control coating by blocking a portion of direct solar near-IR radiation and/or to serve as a low-E coating. This may include partial blocking of visible light. The latter attribute may be beneficial, for example, in climates with lots of sunny days, such as in the states of Arizona and California or in some countries of the Middle East.

In an embodiment, the present disclosure discloses a PMMA pane coated on one of its major surfaces with a sputtered silver-based solar-control coating, such as Ag1 or Ag2, and on the other—with a sputtered TCO-based low-E coating. The TCO-based low-E coating is deposited first. An example is an ITO-based hard coating which is much less susceptible to scratches from, for example, conveyor rolls of a large-area sputter coater than a Ag-based solar-control soft coating. The two coatings have comparable total thicknesses. In addition to providing symmetrical CHE and CTE gradients, such a double-coated pane enables even more enhanced thermal insulation compared to a PMMA pane coated with only a Ag-based coating.

ITO coatings sputter-deposited without intentional heating of the substrate or post-deposition thermal activation are known to have a reduced light transmission. In an embodiment, a PMMA pane is coated on its second major surface with a non-activated low-transmission ITO. These types of inserts are intended, for example, for sunny climates where buildings would benefit from the blockage of not only near-IR radiation but also visible light.

In an embodiment, the ITO-based coating is post-deposition activated by its exposure to flashlight heating—a technology providing pulsed flashes of light which promote selective crystallization of a coating without subjecting the substrate to excessive heat. The activation of a TCO, for example, results in an increased optical transmittance and improved electrical conductivity (thus, in decreased emissivity) as well as improved mechanical durability.

In embodiments, the ITO layer is sandwiched between at least two dielectric layers. Examples of dielectrics include TiOx, SiOx, SiNx, SiOxNy, AlNx, AlOx, AlOxNy, NbOx, etc.

In embodiments, sputtered indium-zinc-oxide (IZO), or aluminum-doped zinc oxide (AZO), or fluorine-doped tin oxide (FTO) [https://doi.org/10.3390/coatings4040732] are used as alternative TCO materials on the opposite to the silver-based solar-control coating surface.

In an embodiment, the second coating also comprises silver, so each major surface of a PMMA pane are coated with a Ag-based solar-control coating.

In an embodiment, one surface is coated with a Ag1 coating and the other one—with a Ag2 coating.

In an embodiment, both coatings are Ag1 coatings.

In an embodiment, both coatings are Ag2 coatings.

In an embodiment, the second coating comprises at least one metal or metal alloy layer. Examples include NiCr, Ni, Cr, Ti, Al, Cu or any alloy thereof, etc.

In an embodiment, the Ag-based coating comprises at least one silver alloy layer. The alloy may comprise silver alloyed with Cu, Al, Ni, Pt, Pd, or Au for added corrosion resistance.

In embodiments, the thickness of the second coating is between about 30 and about 200 nm, preferably between about 50 and 100 nm.

### BRIEF DESCRIPTION OF THE DRAWINGS

The present disclosure can be understood by considering the following drawings and the legend for the reference numerals presented further below:

FIG. 1 is a schematic representation of a plastic pane coated on one of its major surfaces with a sputtered silver-based solar-control low-E coating.

FIG. 2A is a schematic representation of relatively symmetric gradients of moisture concentration from the two major surfaces of an uncoated PMMA pane.

FIG. 2B is a schematic representation of an asymmetric moisture concentration gradient in a plastic pane coated from one side with a coating deposited by atomic layer deposition (ALD).

FIG. 2C is a schematic representation of an asymmetric moisture concentration gradient in a plastic pane coated from one side with a coating deposited by sputtering.

FIG. 3A is a schematic representation of warping of a plastic pane coated on one side with a silver-based solar-control coating and on the opposite side—with an ALD-deposited moisture barrier.

FIG. 3B is a schematic representation of a lack of warping of a plastic pane coated on each of its main surfaces with a sputtered coating.

FIG. 3C is a schematic representation of symmetrical moisture concentration gradients from both sides of a plastic pane coated with a sputtered coating on each of its major surfaces.

The accompanying drawings, which are incorporated in and form a part of this description, illustrate various embodiments of the disclosure, and together with the description, illustrate the principles of the disclosure, and enable those skilled in the art to make and use the disclosure.

### DEFINITION OF THE REFERENCE NUMERALS USED IN THE DRAWINGS

100, 200, 300 Plastic pane
110, 210, 310 Sputtered silver-based solar-control coating
220 Moisture molecule diffused into PMMA pane
230, 330 Coating deposited by atomic layer deposition
340 A representation of warping force from the sputtered silver-based coating side
350 A representation of warping force from the side of the coating deposited on the opposite surface of the pane
360 A representation of warping due to asymmetry in the coefficients of hygroscopic expansion on the opposite sides of the pane
370 A sputtered film deposited on the side of pane opposite to the sputtered silver-based solar-control coating
380 A representation of a lack of warping due to symmetry in the coefficients of hygroscopic expansion on the opposite sides of the pane

### DETAILED DESCRIPTION

A detailed description is provided below to facilitate a thorough understanding of the disclosed embodiments and connections thereof. The description is not limited to any particular example included herein.

Various embodiments and aspects of the disclosure will be described with reference to the details discussed below. The following description and drawings are illustrative of the disclosure and are not to be construed as limiting the disclosure. Numerous specific details are described to provide a thorough understanding of various embodiments of the present disclosure. The Figures are not to scale. Further, in certain instances, well-known or conventional details are not described in order to provide a concise discussion of embodiments of the present disclosure.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure. Unless otherwise specified, the terms “about” and “approximately” mean plus or minus 25 percent or less.

It is to be understood that unless otherwise specified, any specified range or group is as a shorthand way of referring to each and every member of a range or group individually, as well as each and every possible sub-range or sub-group encompassed therein and similarly with respect to any sub-ranges or sub-groups therein. Unless otherwise specified, the present disclosure relates to and explicitly incorporates each and every specific member and combination of sub-ranges or sub-groups.

As used herein, the term “on the order of”, when used in conjunction with a quantity or parameter, refers to a range spanning approximately one tenth to ten times the stated quantity or parameter.

The following terminology is used to describe the subject of the disclosure.

A glazing is an article comprising at least one layer of a transparent material which serves to provide for the transmission of light and/or to provide for viewing of the side opposite the viewer and which is mounted in an opening in a building, vehicle, wall or roof or other framing member or enclosure.

A solar-control coating is a thin-film coating providing partial reduction in the amount of solar radiative heat. The coating generally also exhibits low emissivity (low-E) properties, namely, providing high reflectivity in the mid-infrared range (ambient/room heat).

The coefficient of hygroscopic expansion (CHE) is a ratio that quantifies how moisture sorption affects a material's mechanical characteristics, namely strain in units of (m/m)/wt % H₂O.

The coefficient of thermal expansion (CTE) describes how the size of an object changes with a change in temperature. Specifically, it measures the fractional change in size per degree change in temperature at a constant pressure.

In the first aspect of the present disclosure, therefore, a second coating is provided to equalize the levels of moisture uptake at the two major surfaces of the pane caused by the silver-based solar-control coating. The restored symmetry in moisture profiles within the pane equalizes the moisture-induced strain exerted at both surfaces and caused by CHE and CTE which depend on the levels of moisture in the pane. The benefit of this approach increases for plastic panes with large dimensions, such as those intended for use in large-size architectural windows, in which case inserts with asymmetrical CHE and CTE profiles would inevitably warp.

In a second aspect of the disclosure, the second coating (the one opposite to the silver-based coating) has the additional functionality of also blocking a portion of direct solar radiation and/or to serve as a low-E coating. This may include not only the infrared but also a portion of visible light.

Plastic panes can be made of any polymer material, such as PMMA, PC, PET, etc.

A solar-control coating is typically a thin-film coating applied by any means of deposition, such as physical vacuum deposition (PVD) (preferable for large-scale production due to economic reasons) or chemical vapor deposition (CVD). An example of PVD is magnetron sputtering. An example of CVD is plasma-enhanced chemical deposition. A typical solar-control coating comprises at least one ultra-thin silver layer sandwiched between two dielectric layers or two ultra-thin silver layers alternately sandwiched between three dielectric layers, thus yielding single silver (Ag-1) and dual silver (Ag-2) stacks. The more silver layers are used in the coating, the better the ratio of optical transmission to the reflection of infrared light can be achieved. The typical number of silver layers in a sputtered solar-control coating is between one and three. Other types of deposition techniques can be applied, including pyrolytic, spray, dip, sol-gel, etc. It is preferred that the coatings on the opposite major surfaces of the pane are deposited using the same deposition technique.

One of the significant advantages of a silver based solar-control coating is the fact that silver allows the sharpest transition of its optical transmission curve between the visible and near-IR spectral ranges. In other words, it enables the coating to be highly transparent in the visible while blocking the IR light, thus providing thermal comfort to the building or vehicle occupants. On the flip side, traditional silver-based solar-control coatings are known to be susceptible to environmental corrosion when applied on an exposed surface, even when protected by the deposition of additional thin-film layers. Also, thin silver-based coatings are so-called “soft coatings” which are prone to mechanical damage.

Recent advancements in achieving more mechanically durable and environmentally stable silver-based coatings, however, were disclosed by the inventors of the present disclosure in separate applications [3E Nano U.S. patent applications 63/571,002 and PCT/CA2025/050414 filed]. Examples of improvement include the use of more robust dielectrics, such as aluminum nitride, and corrosion resistant alloys, just to name a few. This allows applying a silver-based solar-control coating on at least one surface of a plastic insert intended to be permanently exposed to the air. The coating on the opposite side may also be a solar-control coating and comprise another silver-based layer stack. It may also be a non-silver based solar-control or low-E material, such as a TCO. Examples include, without any limitation, ITO, IZO, or any other transparent conductive oxide. The second coating may also comprise a material or materials not having electrically conductive properties. In this case, the sole purpose of the second coating is to provide symmetrical permeation rates of environmental moisture into the polymer.

The present disclosure also addresses the situations where humidity levels on the opposite sides of a coated plastic pane are substantially asymmetric. This is the case, for example, when a coated plastic insert is placed on the external surface of an existing window, thus exposing its exterior surface to a much higher humidity. In cases like this, the moisture-control properties of the coatings on both sides of the pane are designed accordingly—through simulations and/or empirical adjustment of total thickness and moisture permeation levels—to equalize their CHE and CTE. In an example embodiment, the maximum difference in thickness of the two coatings is 50%.

In an embodiment, the solar-control coating on the first major surface of a plastic pane comprises one silver layer embedded in a dielectric stack.

In an embodiment, the solar-control coating on the first major surface of a plastic pane comprises two silver layers embedded in a dielectric stack.

In an embodiment, the coating on the second major surface of a plastic pane comprises one silver layer embedded in a dielectric stack.

In an embodiment, the coating on the second major surface of a plastic pane comprises two silver layers embedded in a dielectric stack.

In an embodiment, the coating on the second major surface of a plastic pane comprises one ITO layer embedded in a dielectric stack.

In an embodiment, the coating on the second major surface of a plastic pane comprises a dielectric stack.

In an embodiment, a plastic pane, prior to being bonded to glass, is primed with a hard coating, such as wet-processed siloxane. After exposure to UV light, the hard coating forms a glassy surface. The thickness of the hard coating after curing may be between several microns to several millimeters. The hard coating may be applied to both sides or only one side of the polymer pane considering process and application specifics.

In some embodiments, the thickness of the plastic pane ranges from about 1.0 to about 16.0 mm, and preferably from about 3.0 to about 6.0 mm.

In some embodiments, the thickness of the solar-control coating is from about 100 to about 250 nm thick, preferably about 170 nm thick.

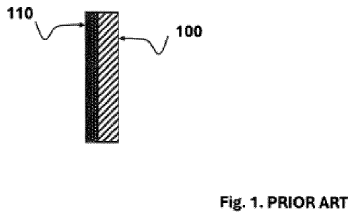

FIG. 1 demonstrates a scenario from prior art when a plastic pane 100 is coated on one side with a sputtered silver-based solar-control coating 110. The pane is made of polycarbonate (PC), polymethyl methacrylate (PMMA), polyethylene terephthalate (PET), or any other plastic material. The coating may be any silver-based solar-control, such as single-, double-, or triple-silver coating.

The silver layer or layers may be made of pure silver or a silver alloy, such as an alloy of silver with Cu, Al, Pd, Pt, Ni, or another metal or a combination of metals.

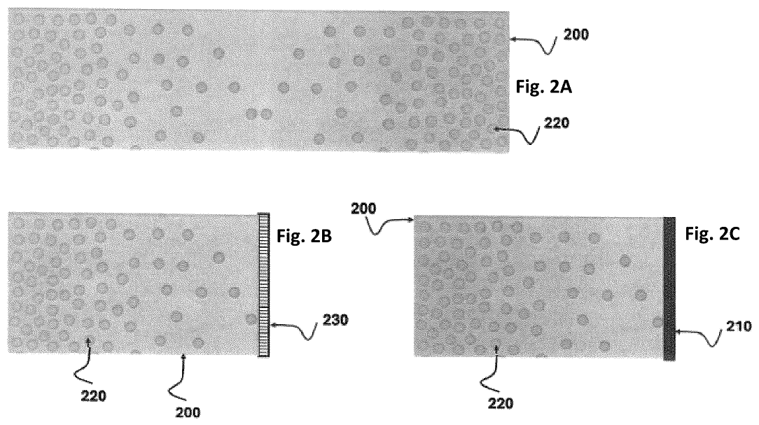

FIG. 2A demonstrates symmetric concentration gradients of permeated environmental moisture molecules 220 into an uncoated pane 200 from its two major surfaces. Such symmetry explains the experimentally observed linear expansion of a plastic pane without significant warping.

FIG. 2B is a schematic representation of asymmetric concentration gradients of permeated moisture molecules 220 from the two major surfaces of a pane 200 coated on its right surface with an exemplary well-performing moisture barrier 230, such as a coating deposited by ALD, a process yielding a low pinhole density. Such asymmetry explains the experimentally observed non-uniform linear expansion of a coated plastic pane showing a significant warping when the coated side forms a concave surface.

FIG. 2C is a schematic representation of asymmetric concentration gradients of permeated moisture molecules 220 from the two major surfaces of a pane 200 coated on its right surface with an exemplary sputtered coating 210, such as a silver-based solar-control coating yielding a moderate pinhole density. Such asymmetry explains the experimentally observed non-uniform linear expansion of a coated plastic pane showing a moderate warping when the coated side forms a concave surface.

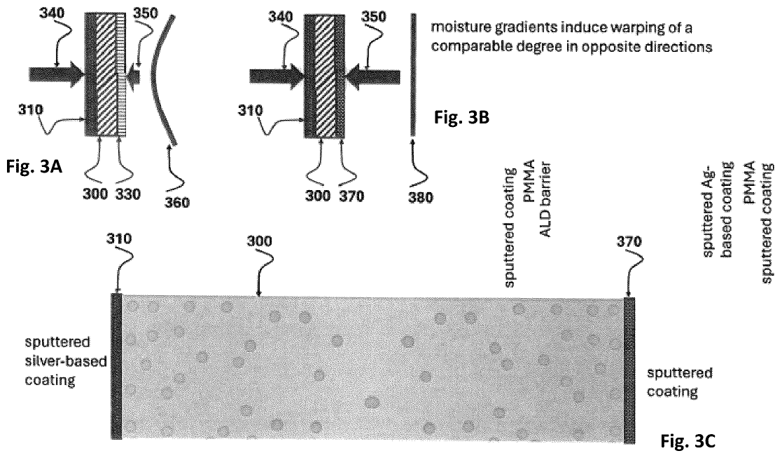

FIG. 3A is a schematic representation of plastic pane 300 coated with a sputtered silver-based solar-control coating 310 on one major surface and with an ALD moisture-barrier coating 330 on the other major surface. Due to the asymmetry in strain vectors 340 and 350, elastic (reversible) warping takes place. This is schematically represented by a bent sheet 360.

FIG. 3B is a schematic representation of plastic pane 300 coated with a sputtered silver-based solar-control coating 310 on one major surface and with a sputtered coating 370 (silver-based or made of any other sputtered material of comparable total thickness) on the other major surface. Due to relative symmetry in strain vectors 340 and 350 in this case, little or no warping is present, which is schematically shown by a flat sheet 380.

FIG. 3C is a schematic representation of relatively symmetric concentration gradients of permeated moisture molecules from the two major surfaces of pane 300 coated with comparable in thickness sputtered coatings 310 and 370.

### Example 1

Example one is a retrofit window insert made of a PMMA, 3 mm thick, coated on one major surface with a Ag2 solar-control coating and on the other major surface—with an ITO-based low-E coating. Both coatings are sputter deposited and are from about 100 to about 250 nm thick, and preferably about 170 nm thick.

### Example 2

Example two is similar to Example one, except that the silver-based solar-control coating is a Ag1 coating having a total thickness from about 100 nm to about 200 nm, and preferably about 150 nm thick.

### Example 3

Example three is similar to Example one, except that the second coating is also silver-based solar-control Ag2 coating having a thickness between about 100 and about 250 nm, preferably between about 170 nm.

### Example 4

Example four is similar to Example one, except that the second coating is an all-dielectric coating having the following layer sequence starting from the substrate: SiOx/AlNx/SiOx. The thickness of the second coating is between about 100 and about 250 nm, preferably about 170 nm.

### Example 5

Example five is similar to Example one, except that the second coating comprises a thin metal (non-silver) layer. The layer sequence starting from the substrate is SiNx/NiCr/SiN. Besides providing a partial moisture barrier, the second coating partially blocks visible transmitted light.

### Example 6

Example six is similar to Example one, except that the low-E coating is post-deposition activated by its exposure to flashlight heating.

### Example 7

Example seven is similar to Example one, except that both silver-based and low-E coatings are post-deposition activated by their exposure to pulsed flashlight heating.

### Example 8

Example eight is similar to Example five, except that the thickness of the second coating is greater than the thickness of the silver-based solar-control coating by 50%.

### Example 9

Example nine is similar to Example five, except that the thickness of the second coating is smaller than the thickness of the silver-based solar-control coating by 50%.

### Example 10

Example ten is similar to Example three, wherein both coatings comprise a nickel chromium (NiCr) blocker layer immediately above and in direct contact with each silver-based functional layer.

### Example 11

Example eleven is similar to Example three, wherein both coatings comprise a nickel chromium nitride (NiCrNx) blocker layer immediately above and in direct contact with each silver-based functional layer. It is noted that x is not well defined for several reasons, the stoichiometry is: a) never well defined and in most cases is tuned empirically; b) never uniform across the thickness of these extremely thin films; and 3) often not well reproducible. This applies to x in the compounds in the Examples below.

### Example 12

Example twelve is similar to Example three, wherein both coatings comprise a nickel chromium oxide (NiCrOx) blocker layer immediately above and in direct contact with each silver-based functional layer.

### Example 13

Example thirteen is similar to Example three, wherein both coatings comprise a nickel chromium oxinitride (NiCrOxNx) blocker layer immediately above and in direct contact with each silver-based functional layer.

### Example 14

Example fourteen is similar to Example three, wherein both coatings comprise a nickel nitride (NixN) blocker layer immediately above and in direct contact with each silver-based functional layer.

### Example 15

Example fifteen is similar to Example three, wherein both coatings comprise a nickel oxinitride (NixON) blocker layer immediately above and in direct contact with each silver-based functional layer.

### Example 16

Example sixteen is similar to Example three, wherein both coatings comprise a zinc aluminum oxide (ZnAlOx) seed layer immediately below and in direct contact with each silver-based functional layer. The aluminum concentration in ZnAlOx is 2 wt. %.

### Embodiments

In an embodiment, the present disclosure provides a thermal-insulation window insert comprising a plastic pane having opposed major surfaces and a thickness from about 1.0 to about 16.0 mm, one surface of the pane having located thereon a first coating which is a solar-control coating having a total thickness in a range between about 100 and about 250 nm. This solar-control coating is comprised of at least one silver layer having a thickness in a range from about 5 nm to about 25 nm. The insert includes a second coating deposited on the surface opposed to the surface coated with the first coating and the first and the second coatings are sputter deposited and their thicknesses do not differ by more than 50%.

In an embodiment, the first coating is a sputtered silver-based solar-control coating having one or more silver layers, and wherein the second coating is a transparent-conductive-oxide (TCO) based low-emissivity (low-E) coating.

In an embodiment, the first coating is a sputtered silver-based solar-control coating having one or more silver layers, and the second coating is also a sputtered silver-based solar-control coating having one or more silver layers.

In an embodiment, the transparent-conductive-oxide is any one of indium tin oxide (ITO), zinc oxide (ZnO), indium-zinc-oxide (IZO), or aluminum-doped zinc oxide (AZO), or fluorine-doped tin oxide (FTO).

In an embodiment, the window insert further comprises a first dielectric layer sandwiched between the surface of the plastic pane and the transparent-conductive-oxide.

In an embodiment, the window insert further comprises a second dielectric layer located on the top surface of the transparent-conductive-oxide so that the transparent-conductive-oxide is sandwiched between two dielectric layers.

In an embodiment, the dielectric layers are any one of stoichiometric TiO₂, SiO₂, Si₃N₄, SiOxNy where 0<x<1; 1>y>0, AlN, Al₂O₃, AlOxNy and NbOx.

In an embodiment, the dielectric layers are any one of nonstoichiometric versions of TiO₂, SiO₂, Si₃N₄, SiOxNy where 0<x<1; 1>y>0, AlN, Al₂O₃, AlOxNy and NbOx.

In an embodiment, the the plastic pane has a thickness from about 3.0 to about 6.0 mm.

In an embodiment, the silver layer has a thickness from about 10 nm to about 15 nm.

In an embodiment, the window insert has an architecture and total thickness of the first and second coatings is selected to give substantially the same coefficients of hygroscopic expansion (CHE) and coefficients of thermal expansion (CTE) at both opposed major surfaces of the plastic pane.

In an embodiment, an architecture of the first and second coatings is selected to give coefficients of hygroscopic expansion (CHE) and coefficients of thermal expansion (CTE) at both opposed major surfaces of the plastic pane within about 10% of each other.

In an embodiment, first coating is a sputtered silver-based solar-control coating having at least two silver layers, further comprising an ultra-thin blocker layer deposited directly on top of first Ag closest to the plastic pane, and a color-control layer on a top surface of the ultra-thin blocking layer.

In an embodiment, the ultra-thin blocker' layer has a thickness from about 1 to about 3 nm, and is oxidized NiCr (also expressed as NiCrOx). For NiCrOx, there is no stoichiometric formula. For this reason, all prior art mentions either “oxidized NiCr” or NiCrOx. In addition, this layer is so thin, it is virtually impossible to detect the exact level of oxygen in it. The oxidation level is empirically estimated and adjusted through optical absorption.

In an embodiment, the ultra-thin blocker' layer has a thickness from about 1 to about 3 nm, and is NiCrNx or NiCrOxNy in direct contact with AlN when the latter is present.

In an embodiment, the window insert further comprises an optional top layer of ZnAlOx located directly above the blocker layer.

In an embodiment, the window insert, further comprises an optional wetting layer directly under the second Ag layer and in direct physical contact with the second Ag layer.

In an embodiment, when more than one silver functional layer is present, they are each separated in a stack by at least one of any dielectric layer, an optional blocker and a seed layer, wherein the blocker layer includes one of NiCr, NiCrNx NiCrOx, NiCrOxNy, NixN, or NixON that prevent diffusion of corrosion causing elements from the exposed surface of the coating into the silver-based functional layers, and wherein the seed layers comprise ZnAlOx which results in a better crystallographic orientation and electro-optical properties of the silver-based functional layers. As noted in Example 11 above, x is not well defined for several reasons, the stoichiometry is: a) never well defined and in most cases is tuned empirically; b) never uniform across the thickness of these extremely thin films; and 3) often not well reproducible.

In an embodiment a thermal-insulation window insert comprises a plastic pane having opposed major surfaces and a thickness from about 1.0 to about 16.0 mm. A first optically transparent coating is located on one of the opposed major surfaces of the pane with the first coating being a solar-control coating having a total thickness in a range between about 100 and about 250 nm and comprising at least one silver layer having a thickness in a range from about 5 nm to about 25 nm. A second optically transparent coating is deposited on the surface opposed to the surface coated with the first coating with an architecture of the first and second coatings selected to give coefficients of hygroscopic expansion (CHE) and coefficients of thermal expansion (CTE) at both opposed major surfaces of the plastic pane within about 10% of each other.

1. A thermal-insulation window insert, the insert comprising:
a plastic pane having opposed major surfaces and a thickness from about 1.0 to about 16.0 mm;
a first coating on one of the opposed major surfaces of said pane, the first coating being a solar-control coating having a total thickness in a range between about 100 and about 250 nm and comprising at least one silver layer having a thickness in a range from about 5 nm to about 25 nm; and
a second coating deposited on the surface opposed to the surface coated with the first coating, wherein the first and the second coatings are sputter deposited and their thicknesses do not differ by more than 50%.

2. The thermal-insulation window insert according to claim 1, wherein the first coating is a sputtered silver-based solar-control coating having one or more silver-based functional layers, and wherein the second coating is a transparent-conductive-oxide (TCO) based low-emissivity (low-E) coating.

3. The thermal-insulation window insert according to claim 1, wherein the first coating is a sputtered silver-based solar-control coating having one or more silver-based functional layers, and wherein the second coating is also a sputtered silver-based solar-control coating having one or more silver-based functional layers.

4. The thermal-insulation window insert according to claim 2, wherein the transparent-conductive-oxide is any one of indium tin oxide (ITO), zinc oxide (ZnO), indium-zinc-oxide (IZO), or aluminum-doped zinc oxide (AZO), or fluorine-doped tin oxide (FTO).

5. The thermal-insulation window insert according to claim 2, further comprising a first dielectric layer sandwiched between the surface of the plastic pane and the transparent-conductive-oxide.

6. The thermal-insulation window insert according to claim 5, further comprising a second dielectric layer located on the top surface of the transparent-conductive-oxide so that the transparent-conductive-oxide is sandwiched between two dielectric layers.

7. The thermal-insulation window insert according to claim 3, wherein the dielectric layers are any one of stoichiometric TiO₂, SiO₂, Si₃N₄, SiOxNy where 0<x<1; 1>y>0, AlN, Al₂O₃, AlOxNy and NbOx.

8. The thermal-insulation window insert according to claim 3, wherein the dielectric layers are any one of nonstoichiometric versions of TiO₂, SiO₂, Si₃N₄, SiOxNy where 0<x<1; 1>y>0, AlN, Al₂O₃, AlOxNy and NbOx.

9. The thermal-insulation window insert according to claim 1, wherein the plastic pane has a thickness from about 3.0 to about 6.0 mm.

10. The thermal-insulation window insert according to claim 1, wherein the at least one silver layer functional coating has a thickness from about 10 nm to about 15 nm.

11. The thermal-insulation window insert according to claim 1, wherein an architecture and total thickness of the first and second coatings is selected to give substantially the same coefficients of hygroscopic expansion (CHE) and coefficients of thermal expansion (CTE) at both opposed major surfaces of the plastic pane.

12. The thermal-insulation window insert according to claim 1, wherein an architecture of the first and second coatings is selected to give coefficients of hygroscopic expansion (CHE) and coefficients of thermal expansion (CTE) at both opposed major surfaces of the plastic pane within about 10% of each other.

13. The thermal-insulation window insert according to claim 1, wherein the first coating is a sputtered silver-based solar-control coating having at least two silver layers, further comprising an ultra-thin blocker layer deposited directly on top of first Ag closest to the plastic pane, and a color-control layer on a top surface of the ultra-thin blocking layer.

14. The thermal-insulation window insert according to claim 13, wherein the ultra-thin blocker' layer has a thickness from about 1 to about 3 nm, and is oxidized NiCr (NiCrOx).

15. The thermal-insulation window insert according to claim 13, wherein the ultra-thin blocker' layer has a thickness from about 1 to about 3 nm and is NiCrNx or NiCrOxNy in direct contact with AlN when AlN is present.

16. The thermal-insulation window insert according to claim 14, further comprising an optional top layer of ZnAlOx located directly above the ultra-thin blocker layer.

17. The thermal-insulation window insert according to claim 14, further comprising an optional wetting layer directly under the second Ag layer and in direct physical contact with the second Ag layer.

18. The thermal-insulation window insert according to claim 2, wherein when more than one silver functional layer is present, they are each separated in a stack by at least one of any dielectric layer, an optional blocker and a seed layer, wherein the blocker layer includes one of NiCr, NiCrNx NiCrOx, NiCrOxNy, NixN, or NixON that prevent diffusion of corrosion causing elements from the exposed surface of the coating into the silver-based functional layers, and wherein the seed layers comprise ZnAlOx which results in a better crystallographic orientation and electro-optical properties of the silver-based functional layers.

19. The thermal-insulation window insert according to claim 3, wherein when more than one silver functional layer is present, they are each separated in a stack by at least one of any dielectric layer, an optional blocker and a seed layer, wherein the blocker layer includes one of NiCr, NiCrNx NiCrOx, NiCrOxNy, NixN, or NixON that prevent diffusion of corrosion causing elements from the exposed surface of the coating into the silver-based functional layers, and wherein the seed layers comprise ZnAlOx which results in a better crystallographic orientation and electro-optical properties of the silver-based functional layers.

20. A thermal-insulation window insert, the insert comprising:
a plastic pane having opposed major surfaces and a thickness from about 1.0 to about 16.0 mm;
a first optically transparent coating on one of the opposed major surfaces of said pane, the first coating being a solar-control coating having a total thickness in a range between about 100 and about 250 nm and comprising at least one silver layer having a thickness in a range from about 5 nm to about 25 nm; and
a second optically transparent coating deposited on the surface opposed to the surface coated with the first coating, wherein an architecture of the first and second coatings is selected to give coefficients of hygroscopic expansion (CHE) and coefficients of thermal expansion (CTE) at both opposed major surfaces of the plastic pane within about 10% of each other.

21. The thermal-insulation window insert according to claim 19, wherein the plastic pane has a thickness from about 3.0 to about 6.0 mm.

22. The thermal-insulation window insert according to claim 20, wherein the at least one silver layer has a thickness from about 10 nm to about 15 nm.
